(19) United States
(12) Patent Application Publication
(10) Pub. No.: US 2012/0255771 A1
(43) Pub. Date: Oct. 11, 2012

(54) PACKAGING SUBSTRATE AND METHOD OF FABRICATING THE SAME

(75) Inventors: Wen-Hung Hu, Taoyuan (TW); Chao-Meng Cheng, Taoyuan (TW); Yu-Hsiang Huang, Taoyuan (TW); Ya-Ping Chiou, Taoyuan (TW)

(73) Assignee: UNIMICRON TECHNOLOGY CORPORATION, Taoyuan (TW)

(21) Appl. No.: 13/441,199

(22) Filed: Apr. 6, 2012

(30) Foreign Application Priority Data
Apr. 7, 2011 (TW) 100112018

(51) Int. Cl. H05K 1/11; H05K 3/02

(52) U.S. Cl. 174/266; 427/98.5

(57) ABSTRACT

A packaging substrate includes a core board having a first surface and an opposite second surface; at least a conic through hole formed in the core board and penetrating the first and second surfaces; a plurality of conductive paths formed on a wall of the conic through hole, free from being electrically connected to one another in the conic through hole; and a plurality of first circuits and second circuits disposed on the first and second surfaces of the core board, respectively, and being in contact with peripheries of two ends of the conic through hole, wherein each of the first circuits is electrically connected through each of the conductive paths to each of the second circuits. Compared to the prior art, the packaging substrate has a reduced number of through holes or vias and an increased overall layout density.

### BACKGROUND OF THE INVENTION

1. Field of the Invention

The present invention relates to packaging substrates, and, more particularly, to a packaging substrate having through holes or vias and a method of fabricating the packaging substrate.

2. Description of Related Art

Along with the rapid development of electronic industry, electronic products may have a variety of high-performance functionalities. To meet the packaging requirements of high integration and miniaturization, a packaging substrate has to have a great number of circuits and elements disposed thereon.

Generally, a number of circuits, vias and through holes are formed in the packaging substrate, and a chip is then disposed on the packaging substrate, such that the chip can fan out its electrical connection paths through the circuits, the vias and the through holes.

Referring to FIGS. 1A to 1F, cross sectional diagrams illustrating a method of fabricating through holes of a packaging substrate according to the prior art are provided, wherein FIG. 1F is a cross sectional diagram along a cutting line AA′ of the top view of FIG. 1F′.

As shown in FIG. 1, a core board 10 having a first surface 10a and an opposite second surface 10b is provided. First metal layers 11 are formed on the first surface 10a and the second surface 10b.

As shown in FIG. 1B, a through hole 100 penetrating the first surface 10a, the second surface 10b and the first metal layers 11 is formed.

As shown in FIG. 1C, conductive seed-layers 12 are formed on the surfaces of the first metal layers 11 and the through hole 100.

As shown in FIG. 1D, second metal layers 13 are formed by electroplating on the conductive seed-layers 12. The conductive seed-layers 12 and the second metal layers 13 in the through hole 100 forme a conductive through hole 101.

As shown in FIG. 1E, the through hole 100 is filled with a resin material 14.

As shown in FIGS. 1F and 1F′, the first metal layers 11, the conductive seed-layers 12 and the second metal layers 13 on the first surface 10a and the second surface 10b are patterned to form a first circuit 15a and a second circuit 15b on the first surface 10a and the second surface 10b, respectively. The first circuit 15a and the second circuit 15b are in contact with peripheries of two ends of the conductive through hole 101. Each of the first circuit 15a and the second circuit 15b is composed of the sequentially stacked first metal layer 11, conductive seed-layer 12 and second metal layer 13. The first circuit 15a is electrically connected to the second circuit 15b through the conductive through hole 101.

Referring to FIGS. 2A to 2G, cross sectional diagrams illustrating a method of fabricating vias of a packaging substrate according to the prior art are provided, wherein FIG. 2G is a cross sectional diagram along a cutting line BB′ of the top view of FIG. 2G′.

As shown in FIG. 2A, a substrate body 20 is provided, and a plurality of conductive pads 21 are formed on the substrate body 20.

As shown in FIG. 2B, a dielectric layer 22 is formed on the substrate body 20 and the conductive pads 21.

As shown in FIG. 2C, a plurality of conic vias 220 are formed to penetrate the dielectric layer 22, with the conductive pad 21 being exposed from the conic vias 220. Each of the conic vias 220 has a mouth portion 220a and an opposite bottom portion 220b, and a periphery of the mouth portion 220a has the greatest aperture.

As shown in FIG. 2D, a conductive seed-layer 23 is formed on the conductive pads 21 and the dielectric layer 22.

As shown in FIG. 2E, a resist layer 24 is formed on the conductive seed-layer 23, and has a plurality of resist opening areas 240 for the conic vias 220 and a portion of a top surface of the dielectric layer 22 to be exposed therefrom.

As shown in FIG. 2F, a metal layer 25 is formed by electroplating on the conductive seed-layer 23 in the resist opening areas 240, and a circuit 261 is formed on the top surface of the dielectric layer 22 to be in contact with the periphery of the mouth portion 220a of the conic vias 220. A conductive via 262 is formed on each of the conic vias 220. The circuit 261 and the conductive vias 262 are each formed by the stacked conductive seed-layer 23 and metal layer 25. The circuit 261 is electrically connected to the conductive pads 21 through the conductive vias 262.

As shown in FIGS. 2G and 2G′, the resist layer 24 and the conductive seed-layer 23 covered by the resist layer 24 are removed.

In light of the above methods of fabricating the conductive through holes 101 and the conic vias 220 according to the prior art, the metal layer is formed on the entire conductive seed-layer. In other words, the through holes and the vias are covered by the metal layer completely, and only a conductive path is left. As a result, one conductive through hole or one conductive via can correspondingly connect to only one independent circuit conducting path. Therefore, the area for circuit layout of the packaging substrate is wasted, and thus the layout density of the entire circuit is hard to be improved.

Therefore, how to solve the problems of the prior art is becoming one of the most popular issues in the art.

### SUMMARY OF THE APPLICATION

In view of the various disadvantages of the prior art, one of the purposes of the present invention is to provide a packaging substrate having a high layout density and a method of fabricating the same.

To achieve the purposes, the present invention provides a packaging substrate, comprising: a core board having a first surface and an opposite second surface; at least a conic through hole formed in the core board and penetrating the first surface and the second surface; a plurality of conductive paths formed on a wall of the at least a conic through hole, free from being electrically connected to one another in the at least a conic through hole; and a plurality of first circuits and second circuits formed on the first surface and the second surface of the core board, respectively, and extending to two ends of the at least a conic via for being electrically connected to the conductive paths, such that the first circuits are electrically to the second circuit through the conductive paths, respectively.

The present invention further provides a method of fabricating a packaging substrate, including: providing a core board having a first surface and an opposite second surface; forming first metal layers on the first surface and the second surface, respectively; forming at least a conic through hole penetrating the first surface, the second surface and the first metal layers; forming conductive seed-layers on the first metal layers and a wall of the at least a conic through hole; forming on the conductive seed-layers resist layers having at least a patterned opening area for a portion of the conductive seed-layers on the surface of the conic through hole to be exposed therefrom; removing the exposed portion of the conductive seed-layers; removing the resist layers; forming second metal layers on the conductive seed-layers by electroplating, allowing the conductive seed-layers and the second metal layers on the wall of the at least a conic through hole to form a plurality of conductive paths free from being electrically connected to one another in the at least a conic through hole; and patterning the first metal layers, the conductive seed-layers and the second metal layers to form a plurality of first circuits and second circuits on the first surface and the second surface, respectively, wherein the first circuits and the second circuits are in contact with peripheries of two ends of the at least a conic through hole and are formed by the first metal layers, the conductive seed-layers and the second metal layers that are sequentially stacked, each of the first circuits is electrically connected to each of the second circuits through each of the conductive paths, and the first circuits are free from being electrically connected to one another.

The present invention further provides a packaging substrate, including: a substrate having a plurality of conductive pads formed on a surface thereof; a dielectric layer formed on the substrate and the conductive pads; at least a conic via penetrating the dielectric layer and having a mouth portion and an opposite bottom portion, wherein the mouth portion has a mouth aperture greater in diameter than a bottom aperture of the bottom portion, and the conductive pads are exposed from the at least a conic via; a plurality of conductive paths formed on a wall of the at least a conic via, free from being electrically connected to one another in the at least a conic via, and the conductive paths being electrically connected to the conductive pads, respectively; and a plurality of first circuits formed on a top surface of the dielectric layer and being in contact with a periphery of the mouth portion of the at least a conic via, wherein each of the first circuits is electrically connected to each of the conductive pads through each of the conductive paths.

The present invention further provides a method of fabricating a packaging substrate, including: providing a substrate having a plurality of conductive pads on a surface thereof; forming a dielectric layer on the substrate and the conductive pads; forming at least a conic via penetrating the dielectric layer for the conductive pads to be exposed therefrom, the at least a conic via including a mouth portion and a bottom portion having a bottom aperture less in diameter than a mouth aperture of the mouth portion; forming a conductive seed-layer on the substrate, the conductive pads and the dielectric layer; forming a first resist layer on the conductive seed-layer; forming at least a patterned opening area on the first resist layer to expose a portion of the conductive seed-layer formed between the conductive pads and formed on the at least a conic via; removing the exposed portion of the conductive seed-layer; removing the first resist layer; forming on the conductive seed-layer a second resist layer having at least an opening area for the at least a conic via, the conductive pads and a portion of a top surface of the dielectric layer to be exposed therefrom; forming a metal layer on the conductive seed-layer in the opening area of the resist layer and the conductive pads to form on the top surface of the dielectric layer a plurality of first circuits that are in contact with a periphery of the mouth portion of the conic via, and to form on a wall of the at least a conic via a plurality of conductive paths free from being electrically connected to one another in the at least a conic via, wherein the first circuits and the conductive paths are formed by the stacked conductive seed-layer and the metal layer, and each of the first circuits is electrically connected to each of the conductive pads through each of the conductive paths; and removing the second resist layer and the conductive seed-layer covered by the second resist layer.

It can be known from the above that the present invention has a reduced number of through holes and vias because each of the through holes can connect more than two circuits from one side to the other of the through hole simultaneously and each of the vias can connect more than two circuits to different conductive pads simultaneously. Thus, the substrate is utilized economically, and has an increase wiring density. As a result, the package structure of the present invention has a reduced volume and a low fabrication cost.

### BRIEF DESCRIPTION OF DRAWINGS

FIGS. 1A to 1F are cross sectional diagrams illustrating a method of fabricating a through hole of a packaging substrate according to the prior art, wherein FIG. 1F is a cross sectional diagram along a cutting line AA′ in the top view of FIG. 1F′;

FIGS. 2A to 2G are cross sectional diagrams illustrating a method of fabricating a via of a packaging substrate according to the prior art, wherein FIG. 2G is a cross sectional diagram along a cutting line BB′ in the top view of FIG. 2G′;

FIGS. 3A to 3I are cross sectional diagrams illustrating a method of fabricating a packaging substrate of a first embodiment according to the present invention, wherein FIG. 3I-2 is a different embodiment of FIG. 3I-1, FIGS. 3I-1 and 3I-1′″ are a cross sectional diagram and a stereogram along a cutting line CC′ in FIG. 3I-1′, respectively, FIG. 3I-1″ is a different embodiment according to FIG. 3I-1″, FIG. 3I-2′ and FIG. 3I-2″ are a cross sectional diagram and a stereogram along a cutting line DD′ in FIG. 3I-2′ and FIG. 3I-2″, respectively, and FIG. 3I-2″ is a different embodiment according to FIG. 3I-2′; and

FIGS. 4A to 4K are cross sectional diagrams illustrating a method of fabricating a packaging substrate of a second embodiment according to the present invention, wherein FIG. 4K and FIG. 4K′-2 are a cross sectional diagram and a stereogram along a cutting line EE′ in FIG. 4K′-1, respectively, and FIG. 4K″-1 and FIG. 4K″-2 are different embodiments according to FIG. 4K′-1 and FIG. 4K′-2, respectively.

### DETAILED DESCRIPTION OF PREFERRED EMBODIMENTS

The following illustrates the method of implementation of the present invention by specific embodiments. Whoever has ordinary knowledge in the technical field of the present invention can easily understand the advantages and efficacy of the present invention by the content disclosed in the specification.

### First Embodiment

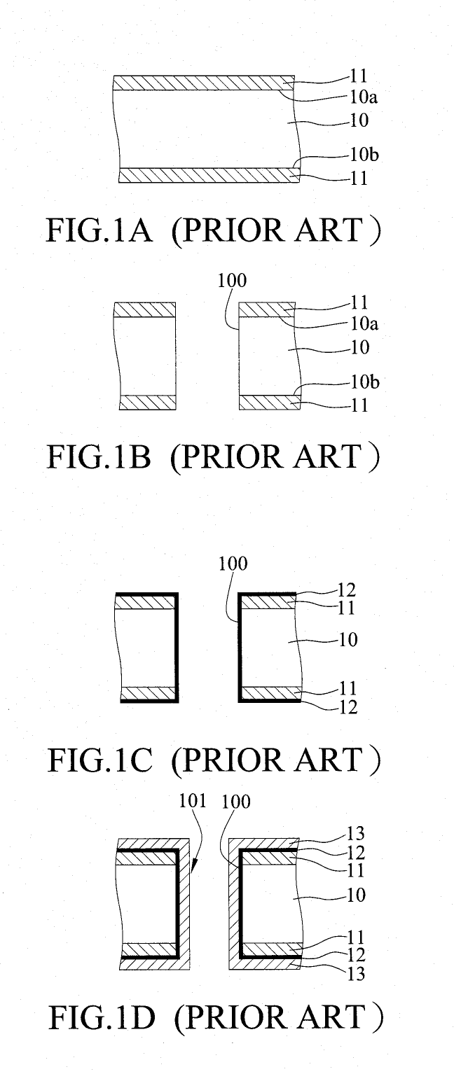

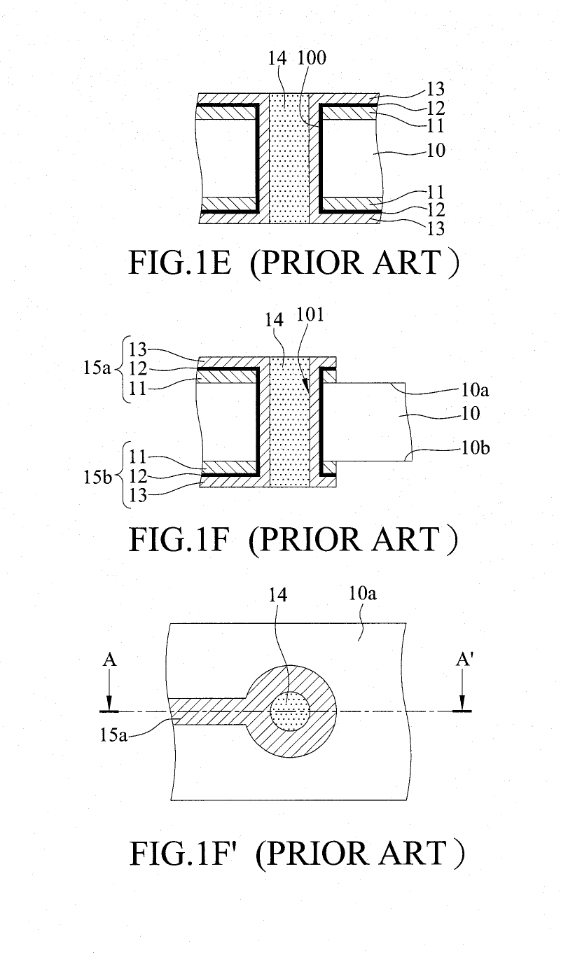

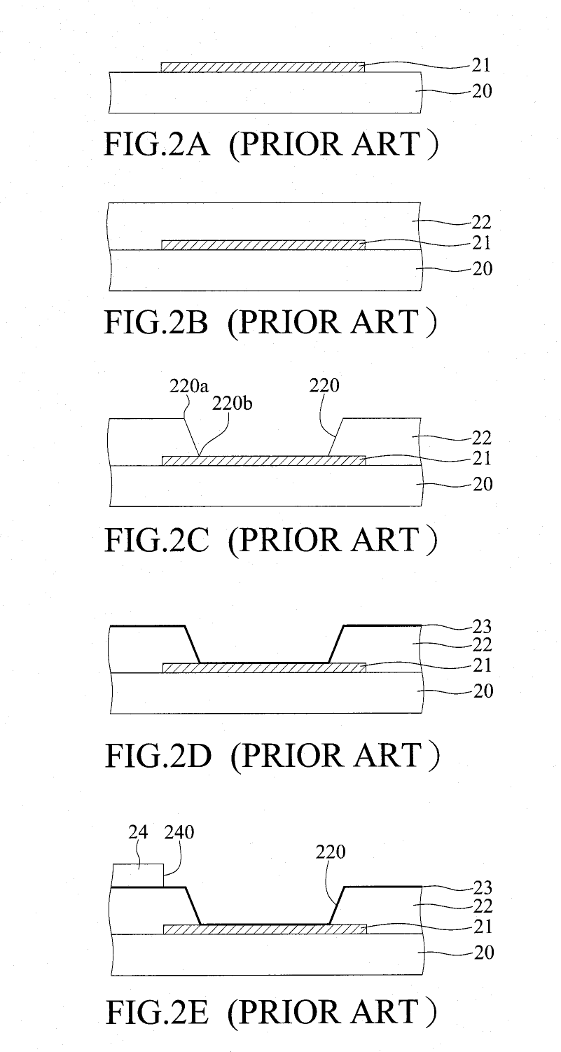

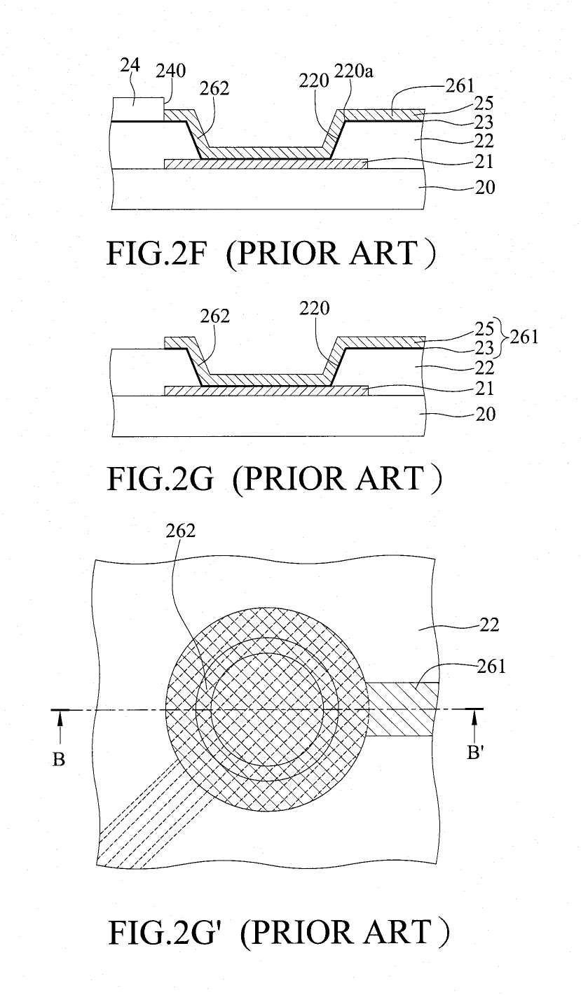

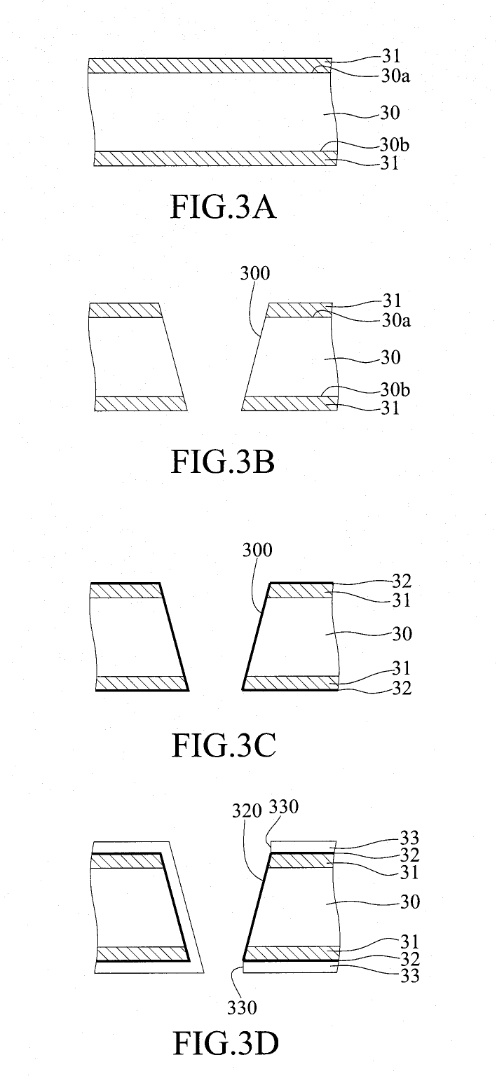

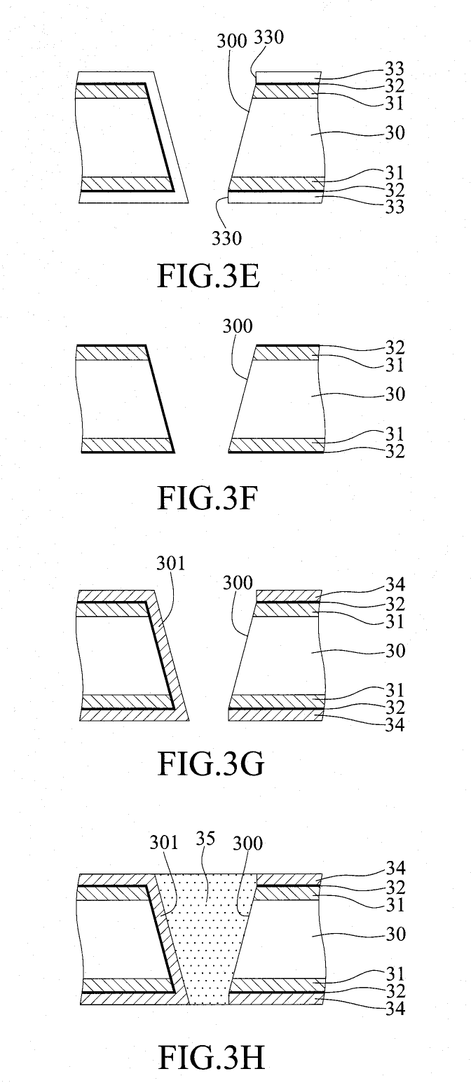

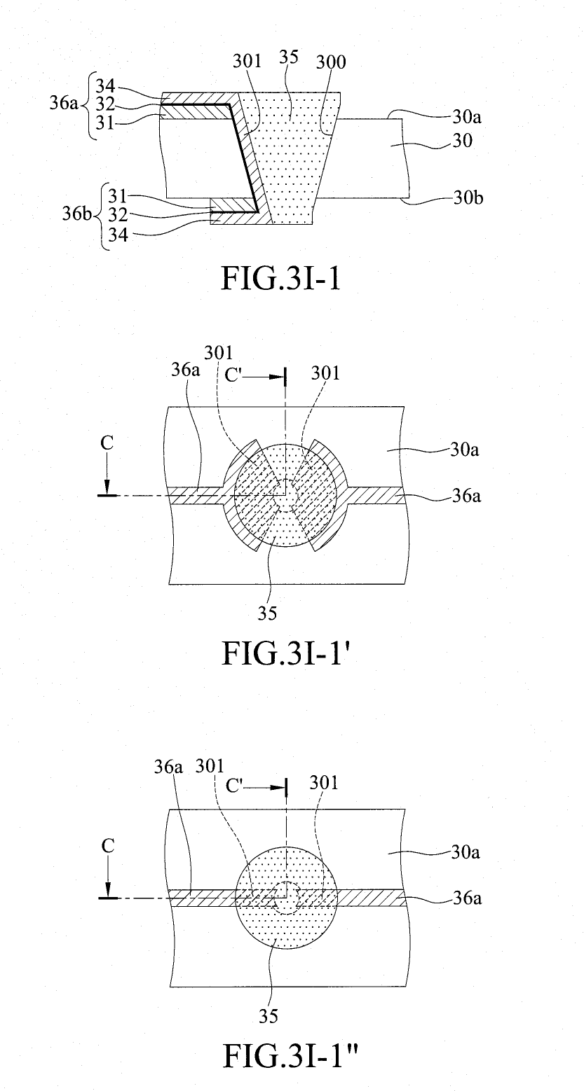

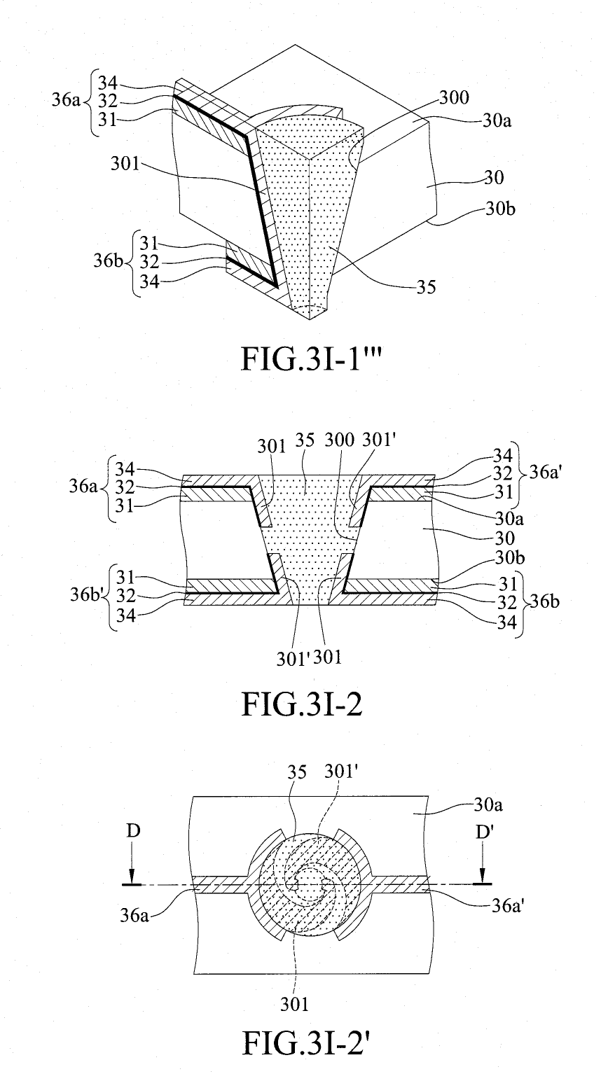

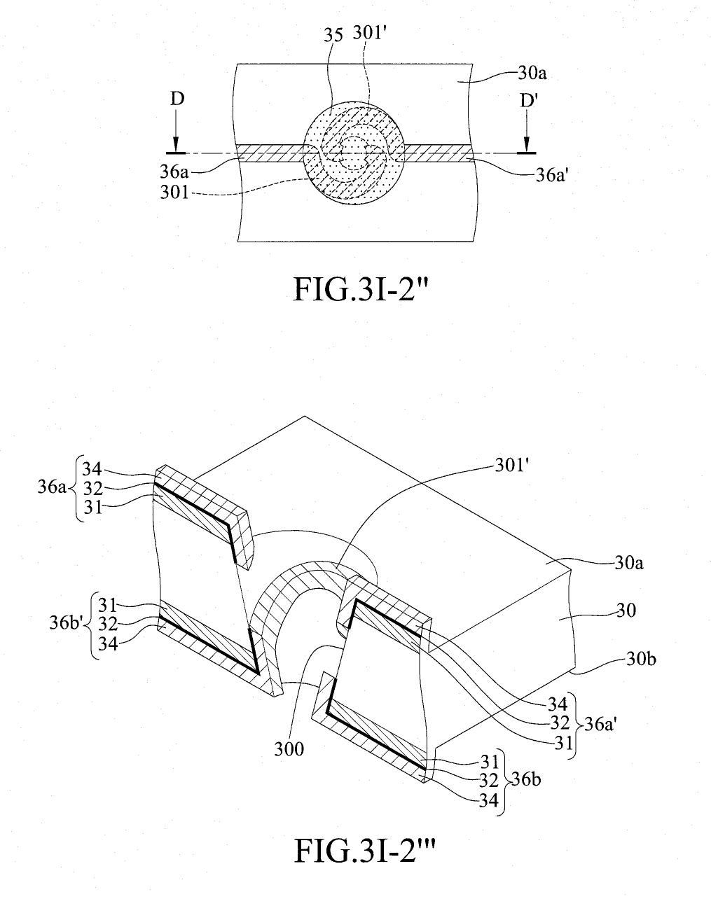

Referring to FIGS. 3A to 3I, cross sectional diagrams illustrating a method of fabricating a packaging substrate of first embodiment according to the present invention are provided, wherein FIG. 3I-2 is a different embodiment from FIG. 3I-1, FIGS. 3I-1 and 3I-1′″ are a cross sectional diagram and a stereogram along a cutting line CC′ in FIG. 3I-1′, respectively, FIG. 3I-1″ is a different embodiment from FIG. 3I-1″, FIG. 3I-2′ and FIG. 3I-2″ are a cross sectional diagram and a stereogram along a cutting line DD′ in FIGS. 3I-2′ and 3I-2″, respectively, and FIG. 3I-2″ is a different embodiment from FIG. 3I-2′.

As shown in FIG. 3A, a core board 30 has a first surface 30a and an opposite second surface 30b, and first metal layers 31 are formed on the first surface 30a and the second surface 30b.

As shown in FIG. 3B, a plurality of conic through holes 300 penetrating the first surface 30a, the second surface 30b and the first metal layers 31 are formed.

As shown in FIG. 3C, conductive seed-layers 32 are formed on the first metal layers 31 and the conic through holes 300.

As shown in FIG. 3D, resist layers 33 are formed on the conductive seed-layers 32. In an embodiment, the resist layers 33 are electrophretic photoresist layers. The resist layers 33 have a patterned mouth portion 330 for a portion of the conductive seed-layers 32 formed on a wall of each of the conic through holes 300 to be exposed therefrom.

As shown in FIG. 3E, the exposed conductive seed-layer 32 is removed.

As shown in FIG. 3F, the resist layers 33 are removed.

As shown in FIG. 3G, second metal layers 34 are formed on the conductive seed-layers 32, and the conductive seed-layers 32 formed on the wall of each of the conic through holes 300 and the second metal layers 34 form a plurality of conductive paths 301 free from being electrically connected to one another in the conic through holes 300.

As shown in FIG. 3H, a resin material 35 fills the conic through holes 300.

As shown in FIGS. 3I-1, 3I-1′, 3I-1″ and 3I-1′″, the first metal layers 31, the conductive seed-layers 32 and the second metal layers 34 formed on the first surface 30a and the second surface 30b are pattered, such that a plurality of the first circuits 36a and second circuits 36b that are in contact with a periphery of two ends of each of the conic through holes 300 are formed on the first surface 30a and the second surface 30b, respectively. Each of the first circuits 36a and the second circuits 36b is formed by the stacked first metal layer 31, conductive seed-layer 32 and second metal layer 34s. The first circuits 36a are electrically connected to the second circuits 36b through the respective conductive paths 301, and any one of the first circuits 36a is not electrically connected to the others.

Alternatively, as shown in another embodiment illustrated in FIGS. 3I-2, 3I-2′, 3I-2″ and 3I-2′″, the first circuits 36a are electrically connected to the second circuits 36b through the conductive paths 301, and the first circuits 36a′ are electrically connected to the second circuits 36b′ through the conductive paths 301.

The present invention further discloses a packaging substrate, including: a core board 30 having a first surface 30a and an opposite second surface 30b; a plurality of conic through holes 300 formed in the core board 30 and penetrating the first surface 30a and the second surface 30b; a plurality of conductive paths 301 formed on a wall of each of the conic through holes 300 free from being electrically connected to one another; and a plurality of first circuits 36a and a plurality of second circuits 36b formed on the first surface 30a and the second surface 30b, respectively, and extending to the two ends of each of the conic through holes 300, and electrically connected to the conductive paths 301, such that the first circuits 36a are electrically connected to the second circuits 36b through the conductive paths 301.

In the packaging substrate, a resin material 35 fills the conic through holes 300, and the conductive path 301 is formed by the conductive seed-layer 32 and the second metal layer 34 formed thereon.

In the packaging substrate of the first embodiment, the first circuits 36a and the second circuits 36b can be formed by the first metal layers 31, the conductive seed-layers 32 and the second metal layers 34 which are in sequence stacked outward from the core board 30.

### Second Embodiment

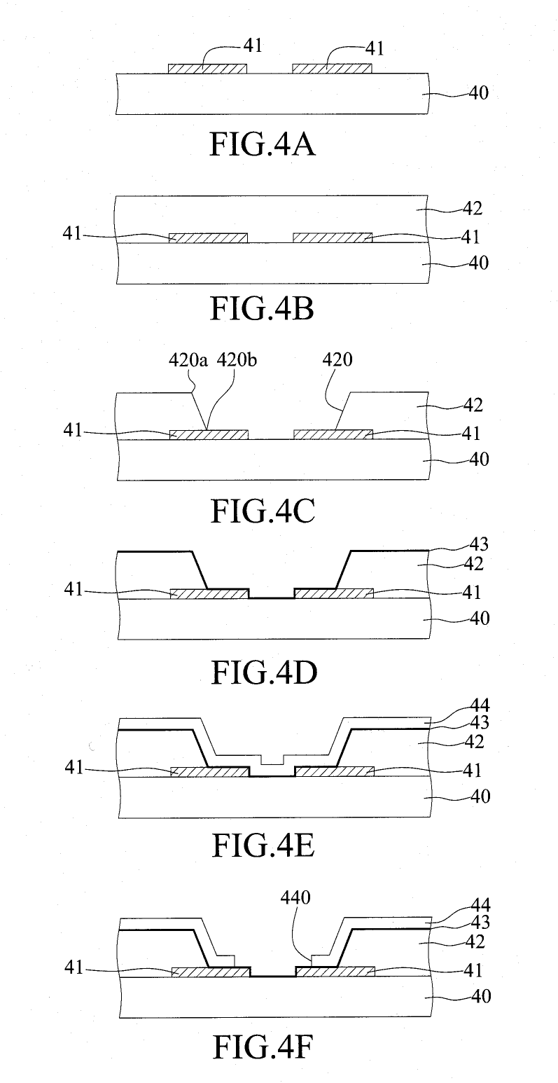

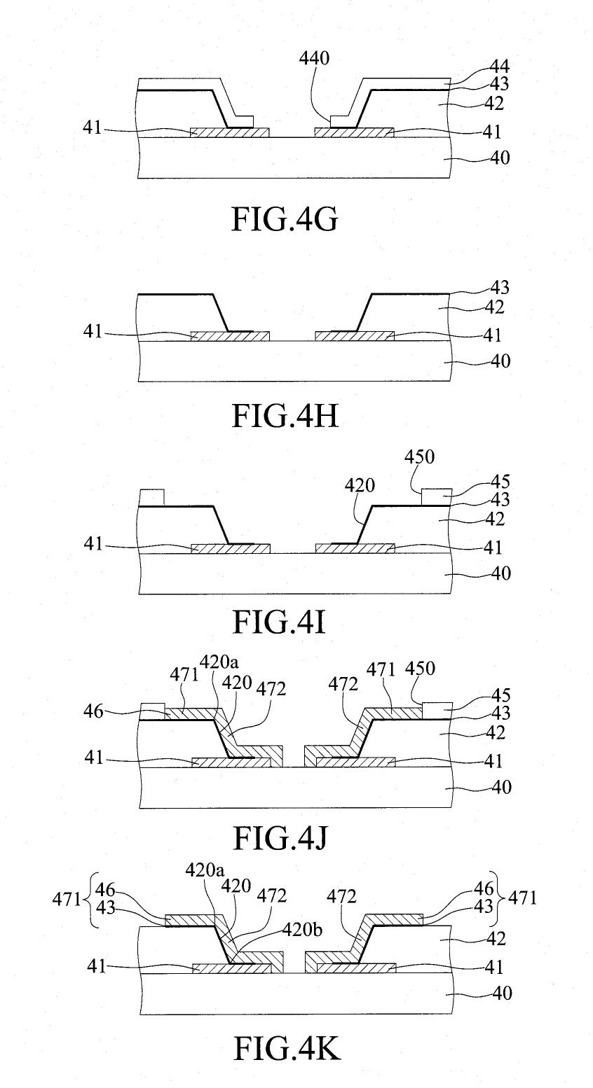

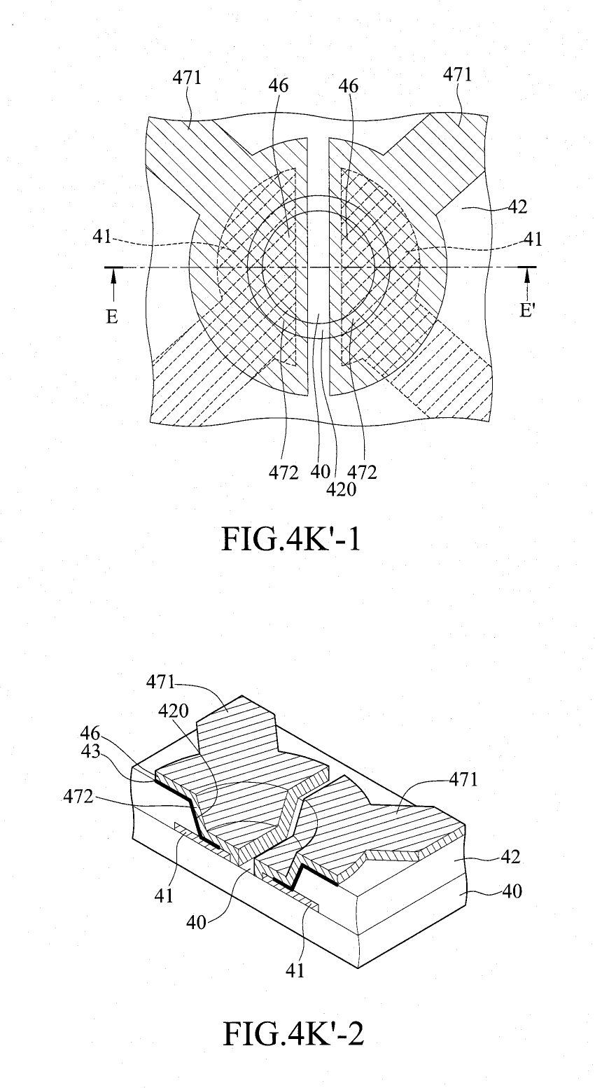

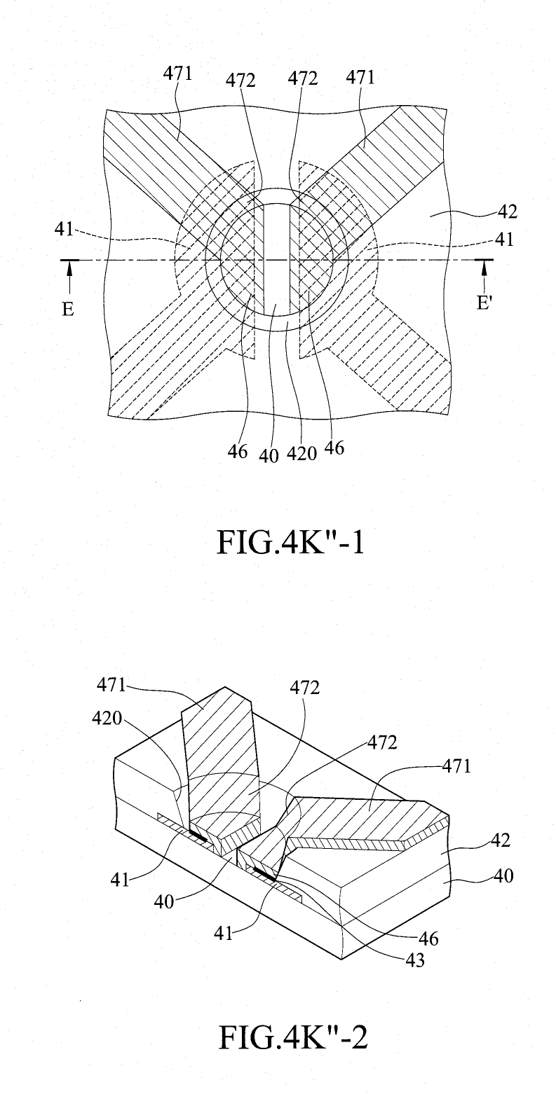

Referring to FIGS. 4A to 4K, cross sectional diagrams illustrating a method of fabricating a packaging substrate of a second embodiment according to the present invention are provided, wherein FIGS. 4K and 4K′-2 are a cross sectional diagram and a stereogram along a cutting line EE′, respectively, and FIGS. 4K″-1 and 4K″-2 are different embodiments of FIG. 4K′-1 and FIG. 4K′-2.

The second embodiment differs from the first embodiment in that vias in the second embodiment are fabricated by reference to the concept applied in the first embodiment.

As shown in FIG. 4A, a substrate 40 having a plurality of conductive pads 41 disposed on a surface thereof is provided. The substrate 40 may be a core board such as a packaging substrate fabricated with a core layer, or an interlayer dielectric layer, such as one of a plurality of dielectric layers in a built-up structure of a final packaging substrate, or one of a plurality of dielectric layers in a final coreless packaging substrate.

As shown in FIG. 4B, a dielectric layer 42 is formed on the substrate 40 and the conductive pads 41.

As shown in FIG. 4C, a plurality of conic vias 420 penetrating the dielectric layer 42 are formed for the conductive pads 41 to be exposed therefrom. Each of the conic vias 420 has a mouth opening 420a and an opposite bottom portion 420b, and the mouth portion 420a has a mouth aperture greater than a bottom aperture of the bottom portion 420b.

As shown in FIG. 4D, a conductive seed-layer 43 is formed on the substrate 40, the conductive pads 41 and the dielectric layer 42.

As shown in FIG. 4E, a first resist layer 44 is formed on the conductive seed-layer 43. In an embodiment, the first resist layer may be an electrophoretic photoresist layer.

As shown in FIG. 4F, a patterned mouth region 440 is formed on the first resist layer 44 for the conductive seed-layer 43 formed between the conductive pads 41 and formed on a portion of the wall of each of the conic vias 420 to be exposed therefrom.

As shown in FIG. 4G the exposed conductive seed-layer 43 is removed.

As shown in FIG. 4H, the first resist layer 44 is removed.

As shown in FIG. 4I, a second resist layer 45 is formed on the conductive seed-layer 43, and has a mouth region 450 for each of the conic vias 420, the conductive pads 41 and a portion of a top surface of the dielectric layer 42 to be exposed therefrom.

As shown in FIG. 4J, a metal layer 46 is formed on the conductive seed-layer 43 and the conductive pad 41 in the mouth region 450 of the resist layer 450 by electroplating, such that a plurality of first circuits 471 that are in contact with the mouth portions 420a of the conic vias 420 are formed on the top surface of the dielectric layer 42, a plurality of conductive paths 472 are formed on the walls of the conic vias 420 free from being electrically connected to one another in the conic vias 420, the first circuits 471 and the conductive paths 472 are formed by the stacked conductive seed-layer 43 and the metal layer 46, and the first circuits 471 are electrically connected to the conductive pads 41 through the respective conductive paths 472.

As shown in FIGS. 4K, 4K′-1, 4K′-2, 4K″-1 and 4K″-2, the second resist layer 45 and the conductive seed-layer 43 covered by the second resist layer 45 are removed.

A packaging substrate is also disclosed according to the second embodiment, including: a substrate 40 having a plurality of conductive pads 41 formed on a surface thereof; a dielectric layer 42 formed on the substrate 40 and the conductive pads 41; a plurality of conic vias 420 penetrating the dielectric layer 42 and each having a mouth portion 420a and an opposite bottom portion 420b, wherein the mouth portion 420a has a mouth aperture greater in diameter than a bottom aperture of the bottom 420b, and the conductive pads 41 are exposed from the conic via 420; a plurality of conductive paths 472 formed on the wall of each of the conic vias 420 free from being electrically connected to one another in each of the conic vias 420, and the conductive paths 472 being electrically connected to the conductive pads 41, respectively; and a plurality of first circuits 471 formed on a top surface of the dielectric layer 42, being in contact with the mouth portions 420a of the conic vias 420, and electrically connected to the conductive pads 41 through the conductive paths 472, respectively.

In the packaging substrate, the conductive paths 472 are formed by the conductive seed-layer 43 and the metal layer 46 formed thereon.

In the packaging substrate of the second embodiment, the first circuit 471 is formed by the conductive seed-layer 43 and the metal layer 46 formed thereon, and the conductive pads 41 are covered with the metal layer 46 extending from the conductive paths 472.

In the packaging substrate, the substrate 40 can be a core board of a packaging substrate having a core layer, one of a plurality of dielectric layers in a built-up structure of the packaging substrate, or one of the dielectric layers in a coreless packaging substrate.

Note that the present invention relates substantially to the through holes and the vias, so only one of the types of the related structure of the circuit and fabrication method thereof is illustratively listed, which shall not limit the scope of the present invention.

To sum up, since each of the through holes can connect more than two circuits from one side to the other of the through hole simultaneously and each of the vias can connect more than two circuits to different conductive pads simultaneously. Thus, the substrate is utilized economically, and has an increase wiring density. As a result, the package structure of the present invention has a reduced volume and a low fabrication cost.

The purpose of the embodiments is for illustrate theory of the present invention and the efficacy thereof rather than limiting the present invention. Whoever have ordinary knowledge in the technical field of the present invention can conduct alteration without violating the spirit and the scope of the present invention. Thus, the rights protection should be listed as the following.

What is claimed is:

1. A packaging substrate, comprising:
a core board having a first surface and an opposite second surface;
at least a conic through hole formed in the core board and penetrating the first surface and the second surface;
a plurality of conductive paths formed on a wall of the at least a conic through hole, without being electrically connected to one another in the at least a conic through hole; and
a plurality of first circuits and second circuits formed on the first surface and the second surface of the core board, respectively, and extending to two ends of the at least a conic through hole for being electrically connected to the conductive paths, such that the first circuits and the second circuits are electrically connected through the conductive paths, respectively.

2. The packaging substrate of claim 1, further comprising a resin material filling the at least a conic through hole.

3. The packaging substrate of claim 1, wherein the conductive paths are formed by a conductive seed-layer and a second metal layer formed on the conductive seed-layer.

4. The packaging substrate of claim 1, wherein the first circuits and the second circuits are formed by a first metal layer, a conductive seed-layer and a second metal layer sequentially stacked on the core board.

5. A method of fabricating a packaging substrate, comprising:
providing a core board having a first surface and an opposite second surface;
forming first metal layers on the first surface and the second surface, respectively;
forming at least a conic through hole penetrating the first surface, the second surface and the first metal layers;
forming conductive seed-layers on the first metal layers and a wall of the at least a conic through hole;
forming on the conductive seed-layers resist layers having a patterned opening area for a portion of the conductive seed-layers on the wall of the at least a conic through hole to be exposed therefrom;
removing the exposed portion of the conductive seed-layers;
removing the resist layers;
forming second metal layers on the conductive seed-layers by electroplating, allowing the conductive seed-layers and the second metal layers on the wall of the at least a conic through hole to form a plurality of conductive paths that are free from being electrically connected to one another in the at least a conic through hole; and
patterning the first metal layers, the conductive seed-layers and the second metal layers to form a plurality of first circuits and second circuits on the first surface and the second surface, respectively, wherein the first circuits and the second circuits are in contact with peripheries of two ends of the at least a conic through hole, and are formed by the first metal layers, the conductive seed-layers and the second metal layers that are sequentially stacked, each of the first circuits is electrically connected to each of the second circuits through each of the conductive paths, and the first circuits are free from being electrically connected to one another.

6. The method of claim 5, further comprising filling the at least a conic through hole with a resin material before patterning the second metal layer, the conductive seed-layer and the first metal layer.

7. The method of claim 5, wherein the resist layer is an electrophoretic photoresist layer.

8. A packaging substrate, comprising:
a substrate having a plurality of conductive pads disposed on a surface thereof;
a dielectric layer formed on the substrate and the conductive pads;
at least a conic via penetrating the dielectric layer and having a mouth portion and an opposite bottom portion, wherein the mouth portion has a mouth aperture greater in diameter than a bottom aperture of the bottom portion, and the conductive pads are exposed from the at least a conic via;
a plurality of conductive paths formed on a wall of the at least a conic via without being electrically connected to one another in the at least a conic via, and the conductive paths electrically connecting to the conductive pads, respectively; and
a plurality of first circuits formed on a top surface of the dielectric layer and being in contact with a periphery of the mouth portion of the at least a conic via, wherein each of the first circuits is electrically connected to each of the conductive pads through each of the conductive paths.

9. The packaging substrate of claim 8, wherein the conductive paths are formed by a conductive seed-layer and a metal layer formed on the conductive seed-layer.

10. The packaging substrate of claim 8, wherein the first circuits are formed by a conductive seed-layer and a metal layer formed on the conductive seed-layer.

11. The packaging substrate of claim 8, wherein the conductive pads are covered by a metal layer extending from the conductive paths.

12. The packaging substrate of claim 8, wherein the substrate is a core board or an interlayer dielectric layer.

13. A method of fabricating a packaging substrate, comprising:
providing a substrate having a plurality of conductive pads on a surface thereof;
forming a dielectric layer on the substrate and the conductive pads;
forming at least a conic via penetrating the dielectric layer for the conductive pads to be exposed therefrom, the at least a conic via including a mouth portion and a bottom portion having a bottom aperture less in diameter than a mouth aperture of the mouth portion;
forming a conductive seed-layer on the substrate, the conductive pads and the dielectric layer;
forming a first resist layer on the conductive seed-layer;
forming at least a patterned opening area on the first resist layer to expose a portion of the conductive seed-layer formed between the conductive pads and formed on the at least a conic via;
removing the exposed portion of the conductive seed-layer;
removing the first resist layer;
forming on the conductive seed-layer a second resist layer having at least an opening area for the at least a conic via, the conductive pads and a portion of a top surface of the dielectric layer to be exposed therefrom;
forming a metal layer on the conductive seed-layer in the at least an opening area of the resist layer and the conductive pads by electroplating, to form on the top surface of the dielectric layer a plurality of first circuits that are in contact with a periphery of the mouth portion of the at least a conic via, and to form on a wall of the at least a conic via a plurality of conductive paths free from being electrically connected to one another in the conic via, wherein the first circuits and the conductive paths are formed by the stacked conductive seed-layer and the metal layer, and each of the first circuits is electrically connected to each of the conductive pads through each of the conductive paths; and
removing the second resist layer and the conductive seed-layer covered by the second resist layer.

14. The method of claim 13, wherein the first resistance is an electrophoretic photoresist layer.

15. The method of claim 13, wherein the substrate is a core board or an interlayer dielectric layer.
